(19) United States
(12) Patent Application Publication
(10) Pub. No.: US 2007/0279267 A1
(43) Pub. Date: Dec. 6, 2007

(54) COMPRESSED DATA TRANSFER APPARATUS AND COMPRESSED DATA TRANSFER METHOD

(76) Inventor: Takanobu Mukaide, Tachikawa-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 11/697,478

(22) Filed: Apr. 6, 2007

(30) Foreign Application Priority Data
Apr. 21, 2006 (JP) 2006-118082

(51) Int. Cl. H03M 7/00

(52) U.S. Cl. 341/95

(57) ABSTRACT

According to one embodiment, when transferring compressed data having information indicating decoding starting time and frame size attached thereto for each frame which is a decoding unit to a decoding processing section, a compressed data transfer apparatus calculates data size which can be transferred to the decoding processing section within time corresponding to a difference between decoding starting time attached to a specified frame and decoding starting time attached to a frame following the specified frame according to the difference between the decoding starting times, performs the control operation to set frame size of the specified frame equal to the calculated data size and rewrites information indicating frame size attached to the specified frame according to data size when the data size is changed.

### CROSS-REFERENCE TO RELATED APPLICATIONS

This application is based upon and claims the benefit of priority from Japanese Patent Application No. 2006-118082, filed Apr. 21, 2006, the entire contents of which are incorporated herein by reference.

### BACKGROUND

1. Field

One embodiment of the invention relates to a compressed data transfer apparatus and compressed data transfer method which transfer compressed data of each decoding unit to a decoding processing section.

2. Description of the Related Art

As is well known in the art, in recent years, optical disks such as digital versatile disks (DVDs) are widely used as digital recording media. At present, a next-generation DVD for high-definition television which is a so called high-definition (HD)-DVD and in which data can be recorded with density still higher than that of a normal DVD is completed.

In the above type of optical disk, video image and audio data items are subjected to a compressed coding process and then recorded. Therefore, with an optical disk reproducing apparatus which reproduces the optical disk, it is necessary to supply data subjected to the compressed coding process to a decoder and subject the data to a decoding (expanding) process.

In this case, a buffer which stores data read out from the optical disk is provided in the optical disk reproducing apparatus and if the decoder issues a request for data to the buffer, the operation of supplying a preset amount of data from the buffer to the decoder and performing the decoding process is repeatedly performed.

However, as described above, in the configuration in which the decoder issues a request for data to the buffer and data is supplied from the buffer to the decoder, it is necessary to provide an exclusive interface which permits bi-directional communication between the buffer and the decoder. As a result, it becomes disadvantageous in the configuration and processing speed.

In Jpn. Pat. Appln. KOKAI Publication No. 2002-353928, the configuration is disclosed in which if the size of unrecorded coded data which is not stored in a transmission buffer is different from the specified size when creation of coded data of one frame is completed, part of a coding word which configures next coded data is delayed and added to the unrecorded coded data so as to set the size of the unrecorded coded data equal to the specified size.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is a block configuration diagram for illustrating a recording/reproducing apparatus according to one embodiment of this invention.

FIG. 2 is a block configuration diagram for specifically illustrating a decoder section of the recording/reproducing apparatus in the above embodiment.

FIGS. 3A and 3B are diagrams respectively showing examples of the operations of a data modification processing section configuring the decoder section of the recording/reproducing apparatus in the above embodiment.

FIGS. 4A and 4B are diagrams respectively showing other examples of the operations of the data modification processing section configuring the decoder section of the recording/reproducing apparatus in the above embodiment.

FIGS. 5A and 5B are diagrams respectively showing still other examples of the operations of the data modification processing section configuring the decoder section of the recording/reproducing apparatus in the above embodiment.

FIGS. 6A and 6B are diagrams respectively showing other examples of the operations of the data modification processing section configuring the decoder section of the recording/reproducing apparatus in the above embodiment.

FIG. 7 is a flowchart for illustrating part of the processing operation of the data modification processing section configuring the decoder section of the recording/reproducing apparatus in the above embodiment.

FIG. 8 is a flowchart for illustrating the remaining part of the processing operation of the data modification processing section configuring the decoder section of the recording/reproducing apparatus in the above embodiment.

### DETAILED DESCRIPTION

Various embodiments according to the invention will be described hereinafter with reference to the accompanying drawings. In general, according to one embodiment of the invention, when transferring compressed data having information indicating decoding starting time and frame size attached thereto for each frame which is a decoding unit to a decoding processing section, a compressed data transfer apparatus calculates data size which can be transferred to the decoding processing section within time corresponding to a difference between decoding starting time attached to a specified frame and decoding starting time attached to a frame following the specified frame according to the difference between the decoding starting times, performs the control operation to set frame size of the specified frame equal to the calculated data size and rewrites information indicating frame size attached to the specified frame according to data size when the data size is changed.

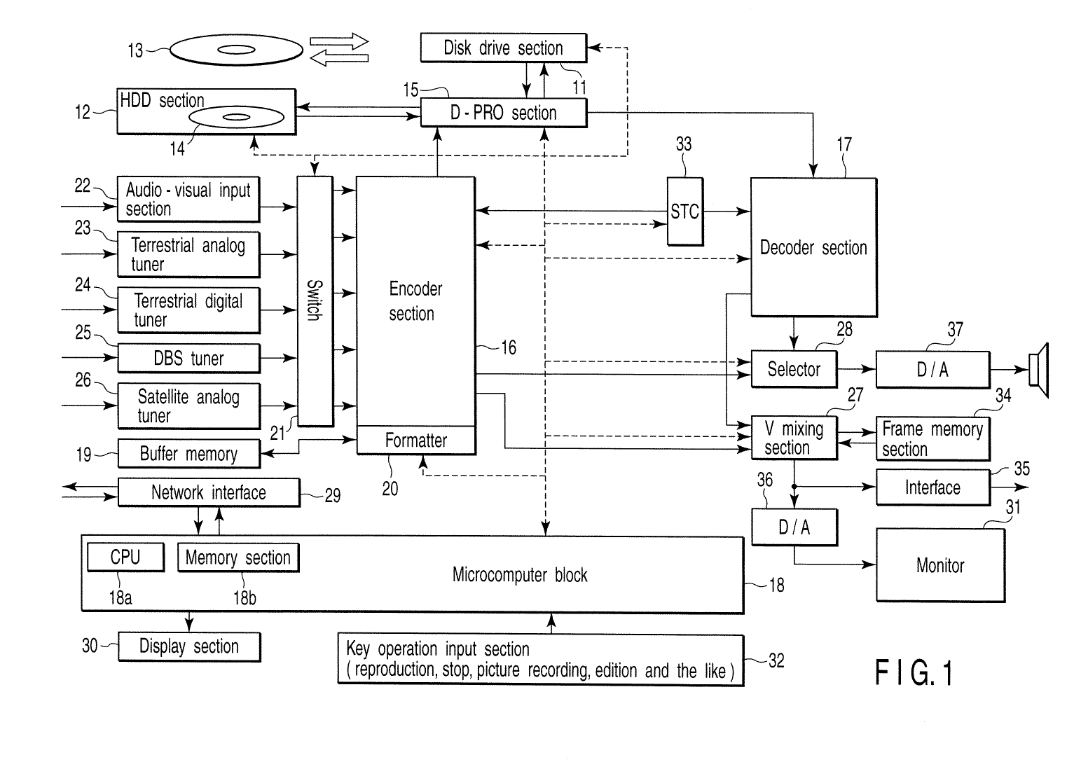

FIG. 1 schematically shows a recording/reproducing apparatus according to one embodiment of this invention. The recording/reproducing apparatus shown in FIG. 1 is provided as an apparatus which can deal with both of an optical disk such as a DVD and a hard disk as information recording media, but as the information recording medium, for example, a semiconductor memory or the like can be used.

In FIG. 1, the block is roughly divided into two portions including the left side portion indicating a main block of a recording section and the right side portion indicating a main block of a reproducing block.

The recording/reproducing apparatus shown in FIG. 1 has two types of disk drive sections including a disk drive section 11 and hard disk drive (HDD) section 12. First, the disk drive section 11 rotates and drives an optical disk 13 used as a first medium which is an information recording medium capable of configuring a video file and performs an information reading/writing operation. The disk drive section 11 has a rotation control system, laser drive system, optical system and the like for the optical disk 13. Further, the HDD section 12 drives a hard disk 14 used as a second medium.

A data processor section 15 can supply recording data to the disk drive section 11 and HDD section 12. Further, it can receive a reproduced signal. The data processor section 15 can deal with data in the recording or reproducing unit and includes a buffer circuit, modulation/demodulation circuit, error correcting section and the like.

The recording/reproducing apparatus shown in FIG. 1 includes an encoder section 16 configuring the recording side, a decoder section 17 configuring the reproducing side and a microcomputer block 18 which controls the operation of the apparatus main body as main constituents. The encoder section 16 includes a transport stream processing section and a plurality of encoders.

The encoder section 16 basically includes video and audio analog-to-digital converters which digitize an input analog video signal and analog audio signal, a video encoder and an audio encoder. Further, it includes a sub video image encoder.

An encoded output from the encoder section 16 is converted into a preset format of a DVD random access memory (DVD-RAM) in a formatter 20 including a buffer memory 19 and then supplied to the data processor section 15. A packet elementary stream extracted from the transport stream may be directly recorded on the hard disk 14 of the HDD section 12 from the encoder section 16 in some cases.

An external analog audio signal and external analog video signal obtained from an audio-visual (audio/video) input section 22 can be input to the encoder section 16 via a switch 21.

Further, reception signals from a terrestrial analog tuner 23, terrestrial digital tuner 24, direct broadcast satellite (DBS) tuner 25 and satellite analog tuner 26 can be selectively input to the encoder section 16 via the switch 21.

When a plurality of encoders are practically used in the encoder section 16, a program received by the terrestrial digital tuner 24 can be recorded in the HDD section 12, and at the same time, a program received by the DBS tuner 25 can be watched.

The encoder section 16 can directly supply a compressed digital video signal and digital audio signal to the formatter 20 when the compressed digital video signal and digital audio signal are directly input. Further, the encoder section 16 can directly supply a digital video signal and audio signal subjected to analog-to-digital conversion to a video mixing section 27 and audio selector 28.

In a Moving Picture Experts Group (MPEG) video encoder contained in the encoder section 16, a digital video signal is converted into a digital video signal compressed at a variable bit rate based on the MPEG2 or MPEG1 standard.

A digital audio signal is converted into a digital audio signal of linear pulse code modulation (PCM) or a digital audio signal compressed at a fixed bit rate based on the MPEG or Audio Compression (AC)-3 standard.

When a sub video image signal is input from the audio-visual input section 22 (such as a signal from a DVD video player with the independent output terminal of a sub video image signal, for example) or when a DVD video signal of the above data structure is broadcasted and received by a television (TV) tuner (not shown), the sub video image signal in the DVD video signal is subjected to an encoding process (run-length coding process) by the sub video image encoder and becomes a bitmap of the sub video image.

The encoded digital video signal, digital audio signal and sub video image data are formed into a pack form by the formatter 20 and respectively become a video pack, audio pack and sub video image pack and they are combined and converted into a format (DVD Video format) specified according to the DVD-video standard or a format (DVD VR format) specified according to the DVD-recording standard. The formatter 20 utilizes the buffer memory 19 at the time of the above conversion process.

The recording/reproducing apparatus shown in FIG. 1 can supply information (packs of video, audio, sub video image data and the like) formatted by the formatter 20 and formed management information to the HDD section 12 or disk drive section 11 via the data processor section 15 and permit the information to be recorded on the hard disk 14 or optical disk 13.

Further, information recorded on the hard disk 14 or optical disk 13 can be respectively recorded on the optical disk 13 or hard disk 14 via the data processor section 15 and disk drive section 11.

The editing process of partly deleting video objects of plural programs recorded on the hard disk 14 or optical disk 13 or connecting objects of different programs can also be performed.

The microcomputer block 18 includes a central processing unit (CPU) 18a and a memory section 18b including a read-only memory (ROM) in which a control program or the like is stored, a RAM used to provide a work area required for execution of the program, a nonvolatile memory in which various types of setting information items are stored and the like.

Further, the microcomputer block 18 can be connected to an external network via a network interface 29. Thus, it becomes also possible to fetch electronic program guide information (dynamic electronic program guide [DEPG]) or the like from an external server.

The CPU 18a of the microcomputer block 18 performs a faulty location detecting process, unrecorded area detecting process, recording information recorded position setting process, universal disk format (UDF) recording process, AV address setting process and the like by using the RAM as a work area according to the control program stored in the ROM of the memory section 18b.

Further, the microcomputer block 18 includes various types of information processing sections required for generally controlling the respective blocks of the recording/reproducing apparatus. Although not shown in the drawing, the information processing section includes a directory detecting section, video manager (VMG) information (whole video management information) creating section, copy-associated information detecting section, copying and scrambling information (RDI) processing section, packet header processing section, sequence header processing section, aspect ratio information processing section and the like.

In addition, the microcomputer block 18 includes an edition-time management information control section which is a control section for management information at the time of execution of the edition process and a recording-time management information control section which is a control section for management information at the time of execution of the recording process.

The contents to be notified to the user among the execution results of the microcomputer block 18 are displayed on a display section 30 of the recording/reproducing apparatus or displayed by on-screen display (OSD) on a monitor display 31.

Further, the microcomputer block 18 has a key operation input section 32 which generates an operation signal to operate the recording/reproducing apparatus. For example, the key operation input section 32 corresponds to operation switches provided on the main body of the recording/reproducing apparatus, a remote controller (not shown) and the like. Further, it may be a personal computer (PC) connected to the recording/reproducing apparatus by use of means such as wired communication or wireless communication (utilizing optical communication or infra-red communication). In either case, the user can perform the process of recording an input video image signal and audio signal, the process of reproducing the recorded contents, the process of editing the recorded contents or the like by operating the key operation input section 32.

Timings at which the microcomputer block 18 controls the disk drive section 11, HDD section 12, data processor section 15, encoder section 16 and/or decoder section 17 can be determined based on time data from a system time clock (STC) 33. The recording and reproducing operations are normally performed in synchronism with the time clock from the STC 33, but the other processes may be performed at timings independent of the timings of the STC 33.

The decoder section 17 includes a separator which separates packs from a signal of the DVD format with the pack structure and takes out the packs, a buffer memory used at the time of pack separation and other signal processing execution times, a video (V) decoder which decodes main video image data (contents of the video pack) separated by the separator, a sub-picture (SP) decoder which decodes sub video image data (contents of the sub video image pack) separated by the separator, and an audio (A) decoder which decodes audio data (contents of the audio pack) separated by the separator. Further, it includes a video processor which adequately synthesizes the decoded main video image and the decoded sub video image, superimposes a menu, highlight button, subtitles and other sub video images on the main video image and outputs the thus superimposed data.

The output video signal of the decoder section 17 is input to the video mixing section 27. In the video mixing section 27, for example, text data items are synthesized. Further, the video mixing section 27 is connected to a line which directly fetches a signal from the TV tuner section and audio-visual input section 22. Further, the video mixing section 27 is connected to a frame memory section 34 used as a buffer memory. An output of the video mixing section 27 is output to the exterior via an interface 35 when it is an analog output and it is output to the exterior via a digital-to-analog converter 36 when it is a digital output.

An output audio signal of the decoder section 17 is supplied to the audio selector 28 and then converted into an analog form by a digital-to-analog converter 37 and then output to the exterior. The audio selector 28 is controlled by a select signal from the microcomputer block 18. Therefore, the audio selector 28 can directly select an audio signal which has passed through the encoder section 16 when the digital signal from the TV tuner section or audio-visual input section 22 is directly monitored.

The formatter 20 of the encoder section 16 creates respective separation information items during the recording operation and periodically supplies them to the CPU 18a of the microcomputer block 18 (information at the group of picture [GOP] head interruption time). As the separation information, the number of packs of video object units (VOBUs), the end address of an intra (I) picture from the VOBU head, reproduction time of VOBU and the like are provided.

At this time, information from an aspect information processing section (not shown) is supplied to the CPU 18a at the record starting time and the CPU 18a creates video object (VOB) stream information (STI). In this case, the STI holds resolution data, aspect data and the like and each decoder section sets the initial condition based on the above information at the reproduction time.

Further, in the recording/reproducing apparatus, a video file is recorded on a DVD one for each disk. In order to continuously perform the reproducing operation without interruption while data is being accessed (subjected to a seek operation), a minimum continuing information unit (size) is determined. The unit is referred to as a contiguous data area (CDA). The CDA size is a multiple of an error correcting code (ECC) block (16 sectors) and data is recorded in the CDA unit in the file system.

The data processor section 15 receives data in the VOBU unit from the formatter 20 of the encoder section 16 and supplies data in the CDA unit to the disk drive section 11 or HDD section 12.

When the CPU 18a of the microcomputer block 18 creates management information required for reproducing recorded data and recognizes a command indicating the end of the data recording operation, it supplies the thus created management information to the data processor section 15. Thus, management information is recorded on the optical disk 13 or hard disk 14. Therefore, the CPU 18a of the microcomputer block 18 receives information (such as separating information) in the data unit from the encoder section 16 while the encoding operation is being performed.

Further, the CPU 18a of the microcomputer block 18 recognizes management information (file system) read out from the optical disk 13 and hard disk 14 at the record starting time and recognizes an unrecorded area of each disk to set a data recording area in the disk via the data processor section 15.

Next, the characteristic configuration and operation of the decoder section 17 of the recording/reproducing apparatus are explained. In the following explanation, the process associated with audio data subjected to the compression coding process is explained, but the process associated with video image data or sub video image data subjected to the compression coding process can also be explained in substantially the same manner.

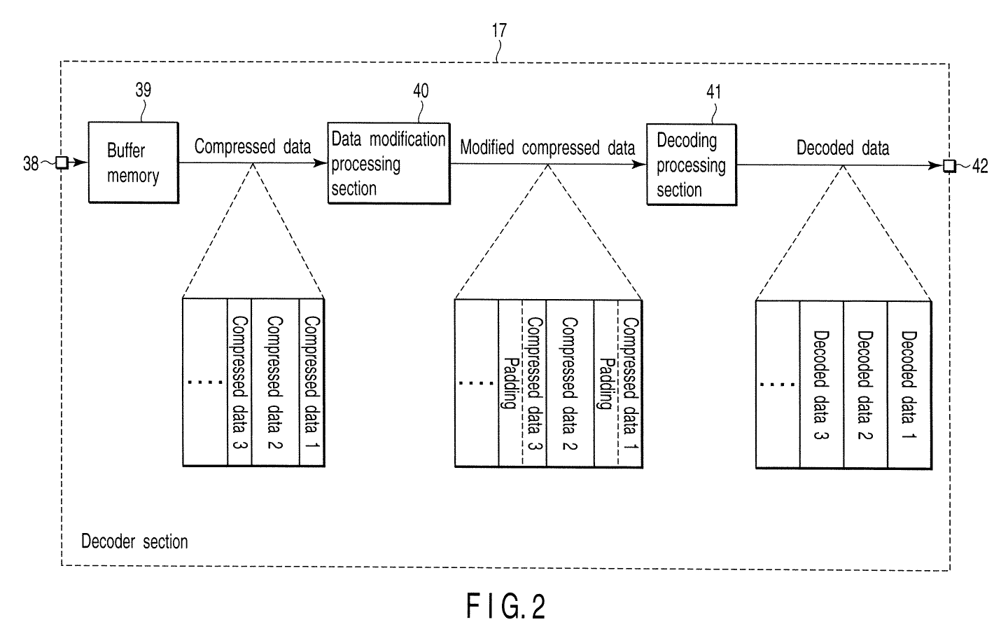

That is, in the decoder section 17, as shown in FIG. 2, audio data subjected to the compression coding process is input to an input terminal 38. The compressed data supplied to the input terminal 38 is first stored in a buffer memory 39 and then supplied to a data modification processing section 40 for each unit (frame) to be subjected to the decoding process.

As will be described in detail later, the data modification processing section 40 performs the data modifying process to supply compressed data of each frame to a decoding processing section 41 at the timing at which the decoding process is started by the decoding processing section 41 at the decoding starting time based on information indicating the decoding starting time attached to each frame and information indicating the frame size.

As one example of the data modification process, the size of data which can be transferred to the decoding processing section 41 within time of a difference between the decoding starting time attached to a frame which is first input and the decoding starting time attached to a frame which follows the above frame is calculated based on the above difference and a data transfer rate (which depends on the sampling frequency in the case of voice data) to the decoding processing section 41.

Then, the thus calculated transfer data size is compared with the frame size attached to the previously input frame. When the transfer data size is larger than the frame size, padding data (which is normally binary zeroes) is added to the previously input frame to set the frame size thereof equal to the transfer data size. Then, information indicating the frame size attached to the previously input frame is rewritten according to modification of the frame size by addition of the padding data and then transferred to the decoding processing section 41.

Thus, the frame which follows the previously input frame is transferred to the decoding processing section 41 at the decoding starting time attached to the frame. As a result, the frame is automatically transferred to the decoding processing section 41 at the decoding starting time thereof without causing the decoding processing section 41 to issue a request for data to the buffer memory 39.

In the decoding processing section 41, input frames are sequentially subjected to the decoding process and the decoded data is output from an output terminal 42 to the exterior of the decoder section 17.

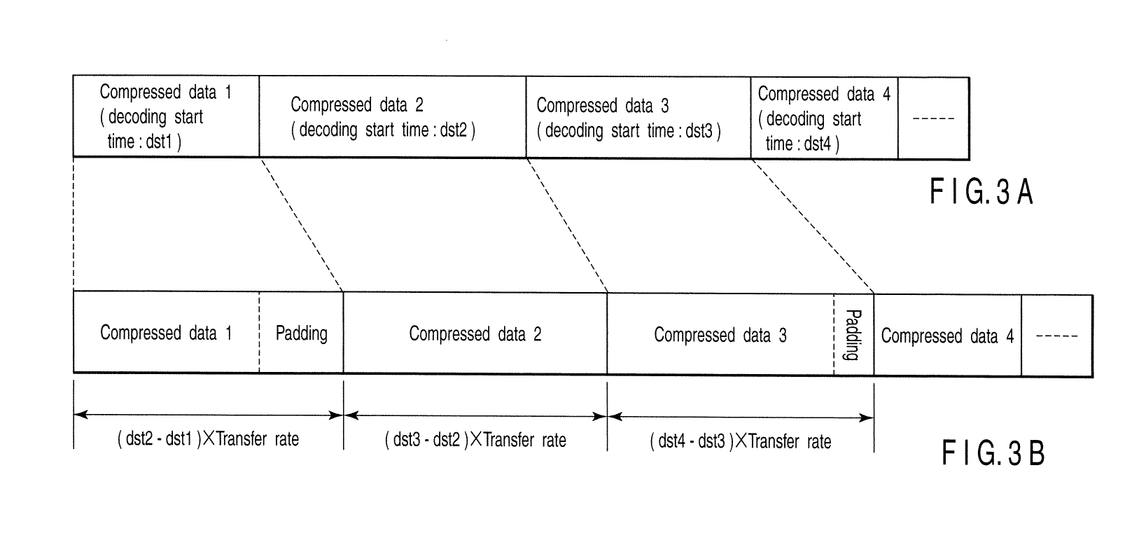

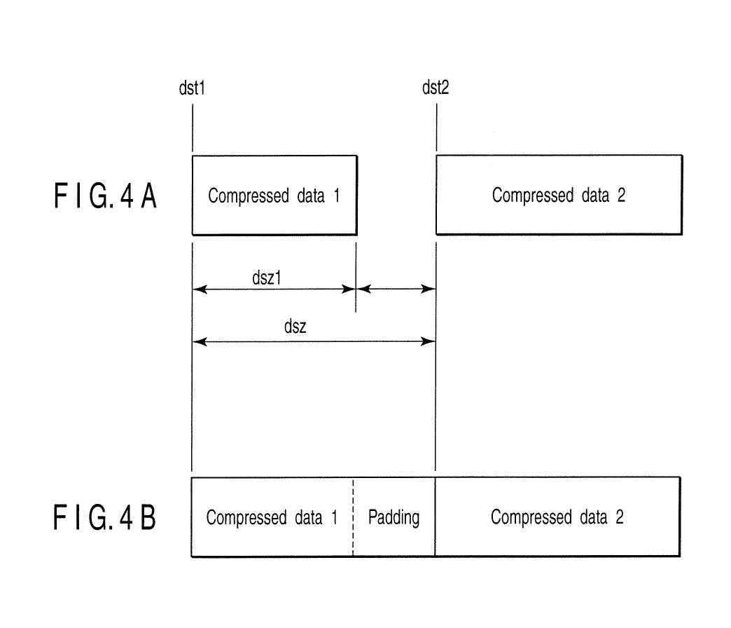

FIGS. 3A, 3B and FIGS. 4A, 4B respectively show examples of the data modification process in the data modification processing section 40. That is, an example in which compressed data items 1, 2, 3, . . . output in the frame unit as shown in FIGS. 3A and 4A from the buffer memory 39 are modified into data items as shown in FIGS. 3B and 4B by the data modification processing section 40 is shown.

First, the data modification processing section 40 acquires decoding starting time dst1 and frame size dsz1 of the compressed data 1 of a preceding frame. Further, the data modification processing section 40 acquires decoding starting time dst2 and frame size dsz2 of the compressed data 2 of a frame next to the preceding frame.

Then, the data modification processing section 40 calculates a difference (dst2−dst1) between the decoding starting times of the preceding frame and next frame and calculates data size dsz which can be transferred to the decoding processing section 41 within the time of the difference (dst2−dst1) by multiplying the difference (dst2−dst1) by a data transfer rate to the decoding processing section 41.

After this, the data modification processing section 40 compares the data transfer size dsz with the frame size dsz1 of the preceding frame. It adds padding data (which is normally binary zeroes) to the compressed data 1 so as to set the frame size of the preceding frame equal to the transfer data size dsz in the case of dsz≧dsz1.

As shown in the example of FIGS. 3A and 3B, since the frame size dsz2 of the compressed data 2 is equal to the transfer data size dsz, no padding data is added. Further, an example in which the frame size dsz3 in the compressed data 3 is smaller than the transfer data size dsz and padding data is added is shown.

Thus, the compressed data 2 which follows the compressed data 1 is automatically supplied to the decoding processing section 41 at the decoding starting time dst2 by adding padding data to the compressed data 1 output from the buffer memory 39. Therefore, it becomes unnecessary to provide an exclusive interface which permits the decoding processing section 41 to issue a request for data with respect to the buffer memory 39 and it becomes advantageous in the configuration and processing speed.

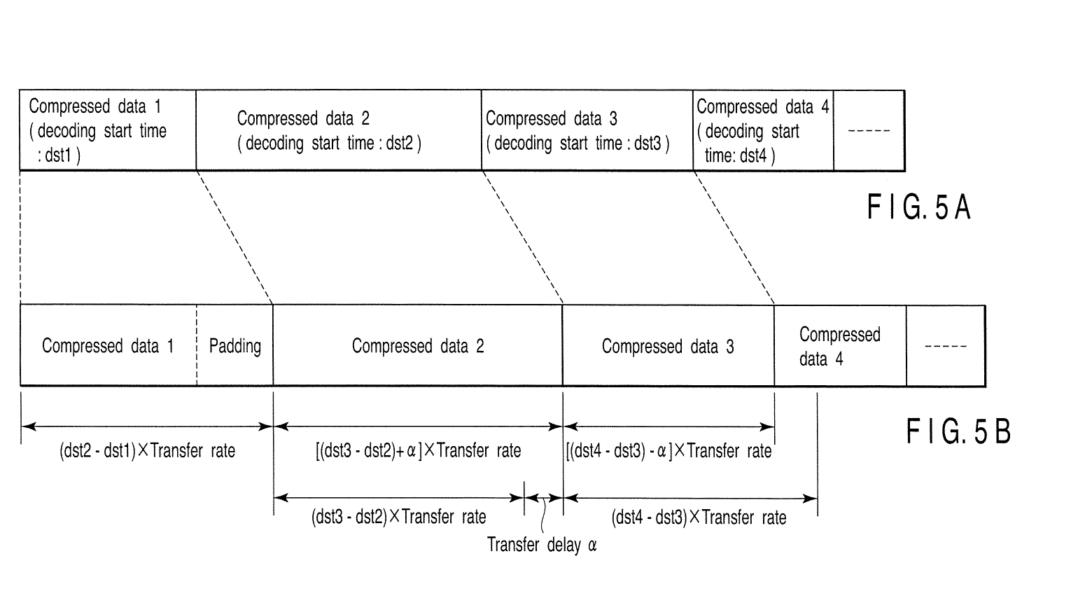

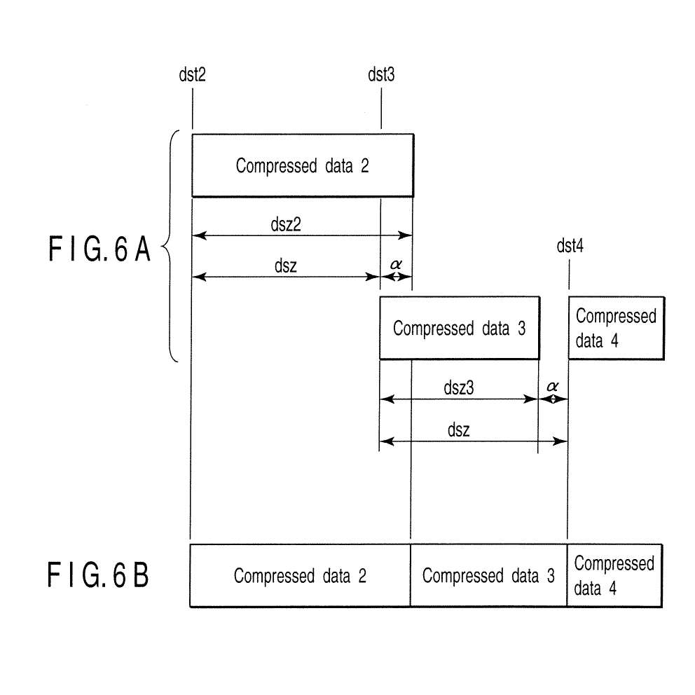

FIGS. 5A, 5B and FIGS. 6A, 6B show other examples of the data modification process of the data modification processing section 40. Also, in this case, an example in which compressed data items 1, 2, 3, . . . output in the frame unit as shown in FIGS. 5A and 6A from the buffer memory 39 are modified into data items as shown in FIGS. 5B and 6B by the data modification processing section 40 is shown.

Padding data is added to the compressed data 1 for the same reason as explained in the examples shown in FIGS. 3A, 3B and FIGS. 4A, 4B.

Then, the data modification processing section 40 acquires decoding starting time dst2 and frame size dsz2 with respect to the compressed data 2 of a preceding frame. Further, the data modification processing section 40 acquires decoding starting time dst3 and frame size dsz3 with respect to the compressed data 3 of a frame next to the preceding frame.

Then, the data modification processing section 40 calculates a difference (dst3−dst2) between the decoding starting times of the preceding frame and next frame and calculates data size dsz which can be transferred to the decoding processing section 41 within the time of the difference (dst3−dst2) by multiplying the difference (dst3−dst2) by a data transfer rate to the decoding processing section 41.

After this, the data modification processing section 40 compares the transfer data size dsz with the frame size dsz2 of the preceding frame. In this case, since dsz is smaller than dsz2, the data modification processing section 40 delays the decoding starting time dst3 of the compressed data 3 by time a corresponding to dsz2−dsz=dsz_diff. That is, the transfer data size of the compressed data 2 is expressed as follows.

[(dst3−dst2)+α]× data transfer rate

In short, the data modification processing section 40 delays transfer of the compressed data 3 by the time α, outputs the same and holds the difference dsz_diff between the frame size dsz2 of the compressed data 2 and the transfer data size dsz which can be transferred to the decoding processing section 41 within the time corresponding to the difference (dst3−dst2).

After this, the data modification processing section 40 calculates a difference (dst4−dst3) between the decoding starting time dst3 of the compressed data 3 of the preceding frame and decoding starting time dst4 of the compressed data 4 of the frame next to the above frame and acquires transfer data size dsz by multiplying the difference (dst4−dst3) by a data transfer rate to the decoding processing section 41. Then, it compares the thus acquired transfer data size dsz with the frame size dsz3 of the preceding frame.

In this case, if the result of comparison indicates the relation of dsz≧dsz3, the data modification processing section 40 assigns time corresponding to the difference, that is, dsz−dsz3 to compensate for transfer delay time caused before. That is, an amount of padding data added to the compressed data 3 is reduced by an amount corresponding to the transfer delay time a caused before to compensate for the decoding starting time dst4 of the compressed data 4.

In the examples shown in FIGS. 5A, 5B and FIGS. 6A, 6B, the transfer delay time α is equal to time a corresponding to a difference between the frame size dsz3 of the compressed data 3 and the transfer data size dsz obtained by multiplying the difference (dst4−dst3) between the decoding starting times dst3 and dst4 of the compressed data items 3 and 4 by the data transfer rate to the decoding processing section 41. Therefore, the transfer delay time α is canceled by setting the amount of padding data added to the compressed data 3 to zero.

Thus, when the frame size of a specified frame is larger than transfer data size between the present frame and a frame next to the present frame, a difference dsz_diff between the sizes is held. Then, when the frame size of a succeeding frame becomes smaller than the transfer data size between the corresponding frame and a frame next to the corresponding frame, an amount of padding data to be added is controlled to compensate for the above difference dsz_diff. Therefore, when attention is paid to a preset period of time, the compressed data of each frame is controlled to be precisely transferred to the decoding processing section 41 at the decoding starting time.

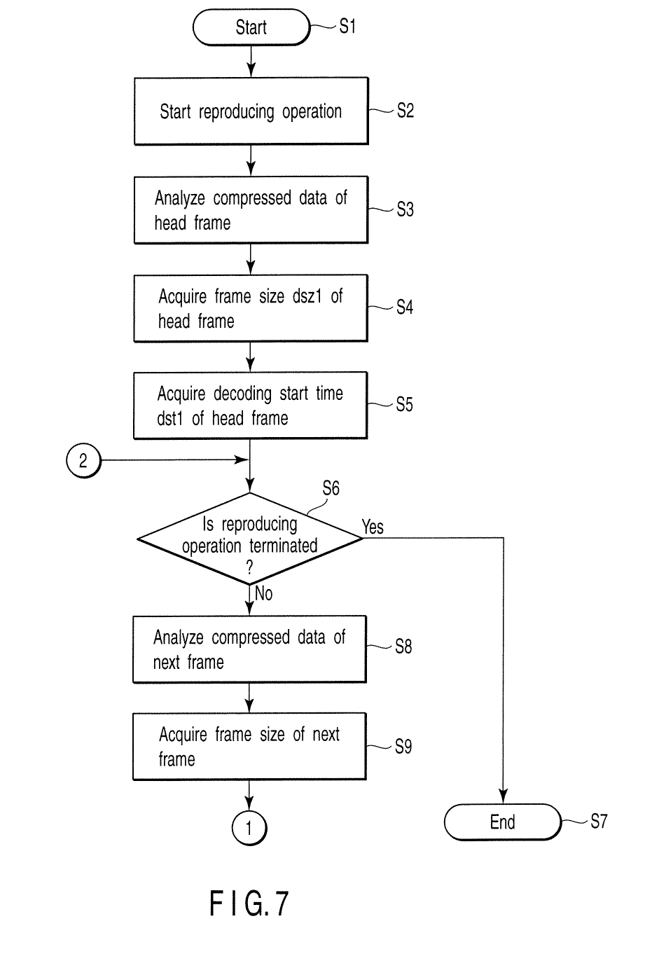

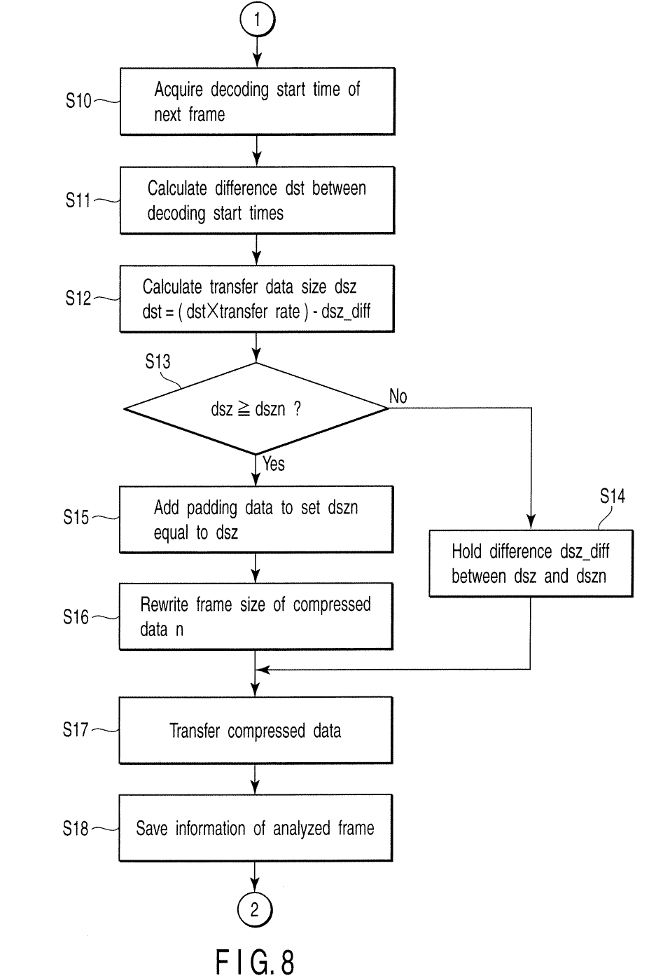

FIGS. 7 and 8 are flowcharts for illustrating the data modification processing operation of the data modification processing section 40. That is, when the process is started (block S1) and the recording/reproducing apparatus starts the reproducing operation in block S2, the data modification processing section 40 analyzes compressed data of a head frame in block S3, acquires frame size dsz1 of the head frame in block S4 and acquires decoding starting time dst1 of the head frame in block S5.

After this, the data modification processing section 40 determines in block S6 whether the reproducing operation is terminated or not. Then, it terminates the process (block S7) when it is determined that the reproducing operation is terminated (“YES”).

If it is determined in block S6 that the reproducing operation is not terminated (“NO”), the data modification processing section 40 analyzes compressed data of a next frame in block S8, acquires frame size of the next frame in block S9 and acquires decoding starting time of the next frame in block S10.

Then, the data modification processing section 40 calculates a difference dst between decoding starting times of the preceding frame and a frame next to the preceding frame in block S11 and calculates transfer data size dsz by multiplying the calculated difference dst between the decoding starting times by the data transfer rate to the decoding processing section 41 in block S12.

If it is detected in block S12 that data size dsz_diff corresponding to the transfer delay time α is held, the data modification processing section 40 calculates transfer data size dsz by subtracting the data size dsz_diff from a value obtained by multiplying the calculated difference dst between the decoding starting times by the data transfer rate to the decoding processing section 41.

After this, the data modification processing section 40 compares the calculated transfer data size dsz with frame size dszn (n is an integral number) of the preceding frame in which the above transfer data size dsz is calculated and determines in block S13 whether the relation of dsz≧dszn is set or not. Then, if it is determined that the relation of dsz≧dszn is not set (“NO”), the data modification processing section 40 holds a difference (dszn−dsz=dsz_diff) between the compared sizes in block S14.

If it is determined in block S13 that the relation of dsz≧dszn is set (“YES”), the data modification processing section 40 adds padding data to compressed data n to set dszn equal to dsz in block S15. Further, it rewrites frame size dszn of the compressed data n to size of data having padding data added thereto in block S16.

After block S14 or S16, the data modification processing section 40 transfers compressed data subjected to a modification process (which may not be subjected to the modification process in same cases) to the decoding processing section 41 in block S17. Then, it saves information (frame size, decoding starting time) of an analyzed frame in block S18 and the process returns to block S6.

In the above embodiment, a case wherein compressed data is transferred from the buffer memory 39 to the decoding processing section 41 in one recording/reproducing apparatus is explained, but this invention is not limited to this case. For example, even when a decoder which performs the decoding process for compressed data is externally attached to an AV equipment which can output the compressed data to the exterior, it becomes unnecessary to install an interface which issues a request to acquire compressed data from the decode side to the AV equipment. Thus, it becomes advantageous in the configuration and processing speed.

Further, the decoding starting time added to each frame may be expressed by absolute time and, for example, it may be expressed by use of relative time with respect to the decoding starting time of a head frame.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein maybe made without departing from the spirit of the inventions. The accompanying claims and their equivalents are intended to cover such forms or modifications as would fall within the scope and spirit of the inventions.

What is claimed is:

1. A compressed data transfer apparatus which transfers compressed data having information indicating decoding starting time and frame size attached thereto for each frame which is a decoding unit to a decoding processing section, comprising:
a calculating section configured to calculate data size transferable to the decoding processing section within time corresponding to a difference between decoding starting time attached to a specified frame and decoding starting time attached to a frame following the specified frame according to the difference between the decoding starting times, and
a control section configured to perform a control operation to set frame size of the specified frame equal to data size calculated in the calculating section and rewrite information indicating the frame size attached to the specified frame according to data size when the data size is changed.

2. The compressed data transfer apparatus according to claim 1, wherein the control section performs a control operation to add padding data to compressed data configuring the specified frame to set the frame size of the specified frame equal to the data size calculated in the calculating section when the frame size of the specified frame is smaller than the data size calculated in the calculating section.

3. The compressed data transfer apparatus according to claim 2, wherein the control section performs a control operation to compare the frame size of the specified frame with the data size calculated in the calculating section to determine whether the frame size of the specified frame is smaller than the data size calculated in the calculating section.

4. The compressed data transfer apparatus according to claim 1, wherein the decoding starting time attached to the frame is expressed by use of one of absolute time and relative time.

5. The compressed data transfer apparatus according to claim 1, wherein the control section performs a control operation to hold a difference between the frame size of the specified frame and the data size calculated in the calculating section without performing the control operation to set the frame size of the specified frame equal to the data size calculated in the calculating section when the frame size of the specified frame is larger than the data size calculated in the calculating section.

6. The compressed data transfer apparatus according to claim 5, wherein the control section performs a control operation to compensate for the difference held by use of a difference between frame size of a frame obtained after the specified frame and the data sizes calculated in the calculating section with respect to the above frame and a frame succeeding thereto when the frame size of the above frame is smaller than the calculated data sizes.

7. A compressed data transfer method which transfers compressed data having information indicating decoding starting time and frame size attached thereto for each frame which is a decoding unit to a decoding processing section, comprising:
a first block of calculating data size transferable to the decoding processing section within time corresponding to a difference between decoding starting time attached to a specified frame and decoding starting time attached to a frame following the specified frame according to the difference between the decoding starting times, and
a second block of performing a control operation to set frame size of the specified frame equal to data size calculated in the first block and rewrite information indicating frame size attached to the specified frame according to data size when the data size is changed.

8. The compressed data transfer method according to claim 7, wherein the second block is performing a control operation to add padding data to compressed data configuring the specified frame to set the frame size of the specified frame equal to the data size calculated in the first block when the frame size of the specified frame is smaller than the data size calculated in the first block.

9. The compressed data transfer method according to claim 8, wherein the second block is performing a control operation to compare the frame size of the specified frame with the data size calculated in the first block to determine whether the frame size of the specified frame is smaller than the data size calculated in the first block.

10. The compressed data transfer method according to claim 7, wherein the decoding starting time attached to the frame is expressed by use of one of absolute time and relative time.

11. The compressed data transfer method according to claim 7, wherein the second block is performing a control operation to hold a difference between the frame size of the specified frame and the data size calculated in the first block without performing the control operation to set the frame size of the specified frame equal to the data size calculated in the first block when the frame size of the specified frame is larger than the data size calculated in the first block.

12. The compressed data transfer method according to claim 11, wherein the second block is performing a control operation to compensate for the difference held by use of a difference between frame size of a frame obtained after the specified frame and the data sizes calculated in the first block with respect to the above frame and a frame succeeding thereto when the frame size of the above frame is smaller than the calculated data sizes.
